(19) United States
(12) Patent Application Publication
(10) Pub. No.: US 2018/0269425 A1
(43) Pub. Date: Sep. 20, 2018

(54) OLED DISPLAY ELEMENT AND OLED DISPLAY DEVICE

(71) Applicant: Wuhan China Star Optoelectronics Technology Co., Ltd., Wuhan City (CN)

(72) Inventors: Donghwan Kim, Wuhan City (CN); Youngsu Kim, Wuhan City (CN); Zhan Shi, Wuhan City (CN)

(21) Appl. No.: 15/539,702

(22) PCT Filed: Apr. 17, 2017
(86) PCT No.: PCT/CN2017/080734

§ 371 Date: Jun. 26, 2017

(30) Foreign Application Priority Data
Mar. 13, 2017 (CN) 201710148142.6

(51) Int. Cl. H01L 51/52; H01L 51/50; H01L 27/32

(52) U.S. Cl. CPC H01L 51/5234; H01L 51/5206; H01L 51/5088; H01L 27/32; H01L 51/5072; H01L 51/5012; H01L 51/5056

(57) ABSTRACT

The present invention provides an OLED display element and an OLED display device. The OLED display element comprises a first electrode (2), an organic layer (3) and a second electrode (5) which are stacked from bottom to top in order, and a stabilizing layer (4) sandwiched between the second electrode (5) and the organic layer (3) or between the first electrode (2) and the organic layer (3); a material of the stabilizing layer (4) comprises a rare earth metal or a mixture of the rare earth metal and a mineral salt, which can maintain the stability of the electrode thin film and enhance the reliability of the OLED display element.

### FIELD OF THE INVENTION

The present invention relates to a display technology field, and more particularly to an OLED display element and an OLED display device.

### BACKGROUND OF THE INVENTION

The Organic Light Emitting Diode (OLED) Element possesses many outstanding properties of self-illumination, low driving voltage, high luminescence efficiency, short response time, high clarity and contrast, near 180° view angle, wide range of working temperature, applicability of flexible display and large scale full color display. It is suitable for wearing electronic equipments, smart phones and flexible display devices.

As shown in FIG. 1, the OLED display device according to prior art typically comprises: a substrate 100, an anode 200 disposed on the substrate 100, an organic layer 300 disposed on the anode 200, a cathode 400 disposed on the organic layer 300 and a package layer 500 disposed on the cathode 400. The organic layer 300 comprises a hole injection layer (HIL) 301, a hole transporting layer (HTL) 302 disposed on the hole injection layer 301, an organic light emitting layer (EML) 303 disposed on the hole transporting layer 302, an electron transporting layer (ETL) 304 disposed on the organic light emitting layer 303 and an electron injection layer (EIL) 305 disposed on the electron transporting layer 304. Furthermore, the electron injection layer 305 in contact with the cathode 400 is usually made of lithium fluoride (LiF) or lithium quinolinol (Liq) as a material. The light emitting principle of the OLED display device is that an electric field is applied to both of the anode 200 and the cathode 400, and holes and electrons are injected to emit light during the recombination thereof in the organic light emitting layer 303.

For the electrode of metal material made by prior art, comparing the electrodes in the form of thinner thin films with the electrodes in the form of thicker thin films, the stability of the metal atoms in the electrodes in the form of thinner thin films is worse. For the top emission type OLED display device with the cathode as the reflective electrode, as the cathode needs to diffuse light or absorb light, silver (Ag), of which the light absorption rate is low, and the reflection or the transmission is higher, is usually used but the thickness of the cathode film is thin, and the reliability is relatively low; with the reasons of the influence of ultraviolet (UV) in external sunlight and the TFT density increase as the resolution increases, and as the cathode is positioned in the UV and high temperature environment for a long time, the metal cohesion phenomenon and cracking phenomenon appear to result in the reliability reduction of the OLED display device, and even the pixel shrinkage phenomenon appears in serious cases.

### SUMMARY OF THE INVENTION

An objective of the present invention is to provide an OLED display element, which can maintain the stability of the electrode thin film and enhance the reliability of the OLED display element.

Another objective of the present invention is to provide an OLED display device, of which the higher reliability is higher and the display stability is better.

For realizing the aforesaid objectives, the present invention first provides an OLED display element, comprising a first electrode, an organic layer and a second electrode which are stacked in order, and a stabilizing layer sandwiched between the second electrode and the organic layer or between the first electrode and the organic layer; a material of the stabilizing layer comprises at least one rare earth metal.

Selectably, the material of the stabilizing layer comprises a mixture of the rare earth metal and a mineral salt.

One of the first electrode and the second electrode is an anode, and the other is a cathode; one of the first electrode and the second electrode is a full transparent or translucent electrode, and the stabilizing layer is sandwiched between the full transparent or translucent electrode and the organic layer.

The organic layer comprises at least a hole injection layer, a hole transporting layer, an organic light emitting layer and an electron transporting layer; the first electrode is deposed on a substrate, and the second electrode is covered by a package layer.

A thickness of the stabilizing layer is 1-50 Å.

In the mixture of the rare earth metal and the inorganic salt, a mass ratio of the rare earth metal and the mineral salt is 1:9-9:1.

A work function of the rare earth metal is not higher than 3.5 eV.

The rare earth metal is a mixture of one or more of lanthanum, ytterbium, cerium, europium, terbium, lutetium, samarium, neodymium and gadolinium.

The mineral salt is a mixture of one or more of lithium fluoride, rubidium iodide, sodium chloride, calcium carbonate and potassium bromide.

The present invention further provides an OLED display device, comprising a plurality of sub pixels, and each sub pixel comprising the aforesaid OLED display element.

The present invention further provides an OLED display element, comprising a first electrode, an organic layer and a second electrode which are stacked in order, and a stabilizing layer sandwiched between the second electrode and the organic layer or between the first electrode and the organic layer; a material of the stabilizing layer comprises at least one rare earth metal;

wherein the material of the stabilizing layer comprises a mixture of the rare earth metal and a mineral salt;

wherein one of the first electrode and the second electrode is an anode, and the other is a cathode; one of the first electrode and the second electrode is a full transparent or translucent electrode, and the stabilizing layer is sandwiched between the full transparent or translucent electrode and the organic layer.

The benefits of the present invention are: in the OLED display element and the OLED display device provided by the present invention, by sandwiching the stabilizing layer comprising a rare earth metal or a mixture of the rare earth metal and a mineral salt between the second electrode and the organic layer or between the first electrode and the organic layer, the stability of the electrode thin film can be maintained to enhance the reliability of the OLED display element so that the OLED display device has the higher reliability and the better display stability.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a cross sectional view diagram of an OLED display device according to prior art;

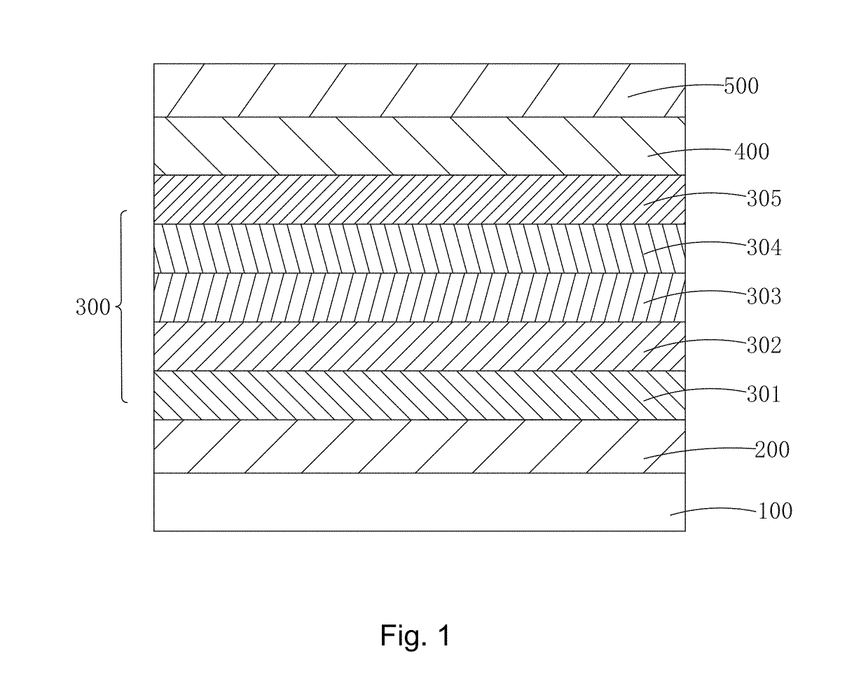

FIG. 2 is a cross sectional view diagram of one embodiment of an OLED display element according to prior art;

FIG. 3A shows the comparison of the microstructures of structure 1-1 before and after heat treatment in the validation experiment;

FIG. 3B shows the comparison of the microstructures of structure 1-2 before and after heat treatment in the validation experiment;

FIG. 3C shows the comparison of the microstructures of structure 1-3 before and after heat treatment in the validation experiment;

FIG. 4A shows the comparison of the microstructures of structure 2-1 before and after heat treatment in the validation experiment;

FIG. 4B shows the comparison of the microstructures of structure 2-2 before and after heat treatment in the validation experiment;

FIG. 4C shows the comparison of the microstructures of structure 2-3 before and after heat treatment in the validation experiment.

### DETAILED DESCRIPTION OF PREFERRED EMBODIMENTS

For better explaining the technical solution and the effect of the present invention, the present invention will be further described in detail with the accompanying drawings and the specific embodiments.

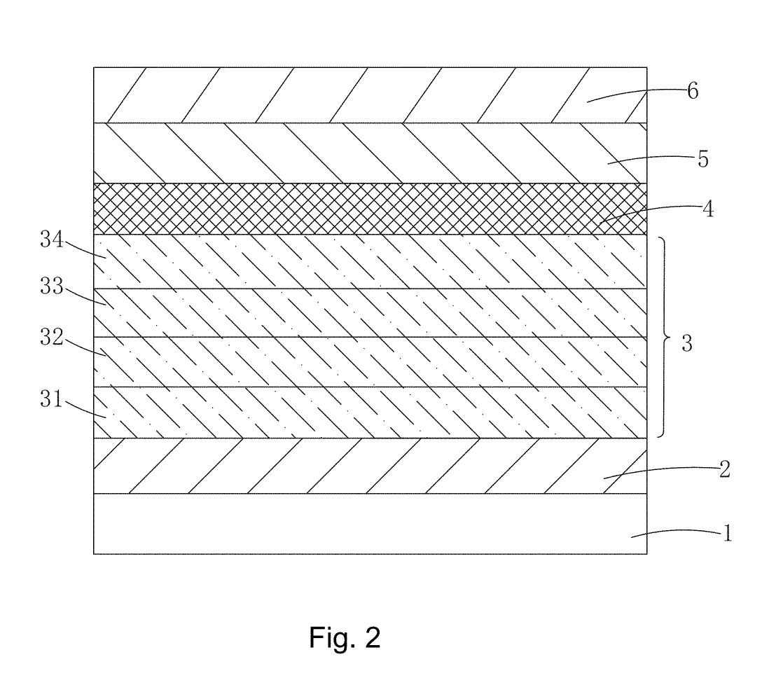

Please refer to FIG. 2. The present invention first provides an OLED display element, comprising a substrate 1 (generally glass material), a first electrode 2, an organic layer 3 and a second electrode 5 which are stacked on the substrate 1 in order, and a stabilizing layer 4 sandwiched between the second electrode 5 and the organic layer 3 or between the first electrode 2 and the organic layer 3; furthermore, a package layer 6 covering on the second electrode 5.

Specifically: the first electrode 2 and the second electrode 5 are metal electrodes in a form of thin films having a thinner thickness.

One of the first electrode 2 and the second electrode 5 is an anode, and the other is a cathode. One of the first electrode 2 and the second electrode 5 is a full transparent or translucent electrode, and the stabilizing layer 4 is sandwiched between the full transparent or translucent electrode and the organic layer 3. For instance, if the OLED display element is a top emission type, the second electrode 5 is a fully transparent or translucent electrode (formed of 70% or more Ag). Then, the stabilizing layer 4 is sandwiched between the second electrode 5 and the organic layer 3 as shown in FIG. 2; if the OLED display element is a bottom emission type, the first electrode 2 is a fully transparent or translucent electrode (formed of 70% or more Ag). Then, the stabilizing layer 4 is sandwiched between the first electrode 2 and the organic layer 3.

The organic layer 3 comprises at least a hole injection layer 31, a hole transporting layer 32, an organic light emitting layer 33 and an electron transporting layer 34, which are stacked from bottom to top or from top to bottom. If the first electrode 2 is an anode and the second electrode 5 is a cathode, the organic layer 3 comprises the hole injection layer 31, the hole transporting layer 32, the organic light emitting layer 33 and the electron transporting layer 34, which are stacked from bottom to top as shown in FIG. 2; if the first electrode 2 is a cathode and the second electrode 5 is an anode, the organic layer 3 comprises the hole injection layer 31, the hole transporting layer 32, the organic light emitting layer 33 and the electron transporting layer 34, which are stacked from top to bottom, and the internal structure of the hole injection layer 31, the hole transporting layer 32, the organic light emitting layer 33 and the electron transporting layer 34 has no difference from prior art. The description is omitted here.

A material of the stabilizing layer 4 comprises at least one rare earth metal. Selectably, the stabilizing layer 4 comprises only a rare earth metal, or comprises a mixture of a rare earth metal and a mineral salt.

Furthermore, a thickness of the stabilizing layer 4 is preferably 1-50 Å and will not affect the absorption of light.

The rare earth metal can be selected from one or more combinations of lanthanum (La), ytterbium (Yb), cerium (Ce), europium (Eu), terbium (Tb), lutetium (Lu), samarium (Sm), neodymium (Nd) and gadolinium (Gd). A work function of the respective rare earth metals as aforementioned is not higher than 3.5 eV, as shown in Table 1 below:

TABLE 1
Rare earth metal elements and corresponding work function values
thereof

| element | work function value/ev |
|---|---|
| La | 3.5 |
| Yb | 2.6 |
| Ce | 2.9 |
| Eu | 2.5 |
| Tb | 3.0 |
| Lu | 3.3 |
| Sm | 2.7 |
| Nd | 3.2 |
| Gd | 2.9 |

In the mixture of the rare earth metal and the mineral salt, a mass ratio of the rare earth metal and the mineral salt is 1:9-9:1; furthermore, the mineral salt is one or more combinations of lithium fluoride (LiF), rubidium iodide (RbI), sodium chloride (NaCl), calcium carbonate (CaCO₃) and potassium bromide (KBr).

In the background of the invention, it has been mentioned that the stability of the metal atoms in the electrodes in the form of thinner thin films is poor, and the reliability is lower with the influence of UV, as the electrode is positioned in the UV and high temperature environment for a long time, the metal cohesion phenomenon and cracking phenomenon appear to result in the reliability reduction of the OLED display device. In comparison with prior art, in the OLED display element of the present invention, stabilizing layer 4 comprising the rare earth metal, or a mixture of the rare earth metal and the mineral salt is sandwiched between the full transparent or translucent electrode and the organic layer 3. As the rare earth metals are in the sixth to seventh cycle and the group III in the periodic table of chemical elements, the atomic size is large and a small amount of rare earth metals can offset the cohesion phenomenon produced by the Ag electrode materials, of which the atomic size is smaller. The rare earth metal has a high thermal conductivity and can absorb a lot of heat from the Ag electrode material. Meanwhile, the work function value of the rare earth metal is low, and the electronic input characteristics are good, which can maintain the thermal stability of the electrode film and enhance the reliability of the OLED display element.

The verification is conducted by experiment: in the structure 1-1, Ag of 200 Å is formed on the glass substrate, and in the structure 1-2, LiF of 20 Å is formed and then Ag of 200 Å is formed on the glass substrate, and in the structures 1-3, Liq of 20 Å is formed and then Ag of 200 Å is formed on the glass substrate; in the structure 2-1, Yb of 20 Å is formed and then Ag of 200 Å is formed on the glass substrate, and in the structure 2-2, Yb and LiF with ratio 1:9 of 20 Å is formed and then Ag of 200 Å is formed on the glass substrate, and in the structure 2-3, Yb and LiF with ratio 9:1 of 20 Å is formed and then Ag of 200 Å is formed on the glass substrate; after the completion of the aforesaid six structures, the comparative observation is implemented to them after keeping in the environment of 100 Celsius degree for 24 hours.

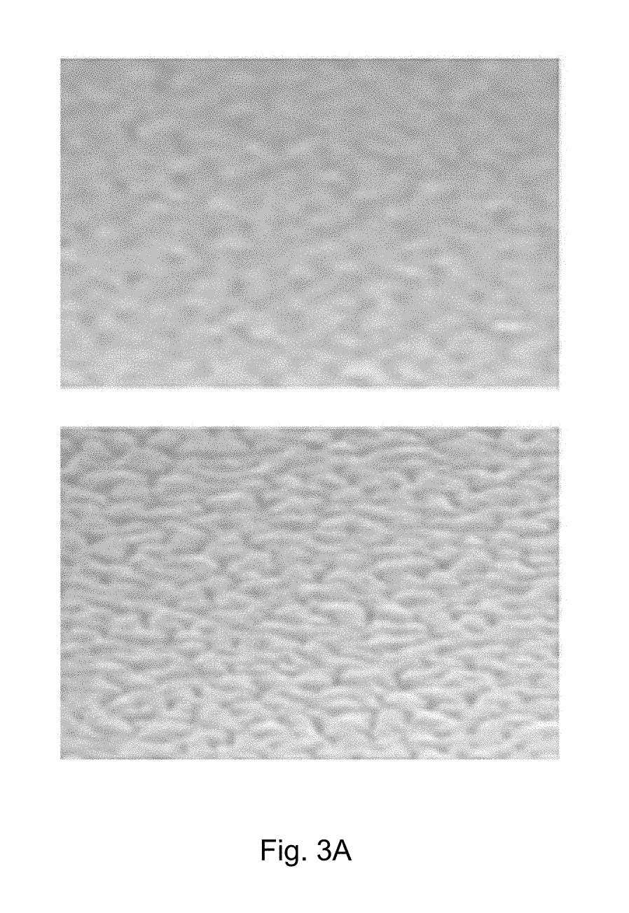

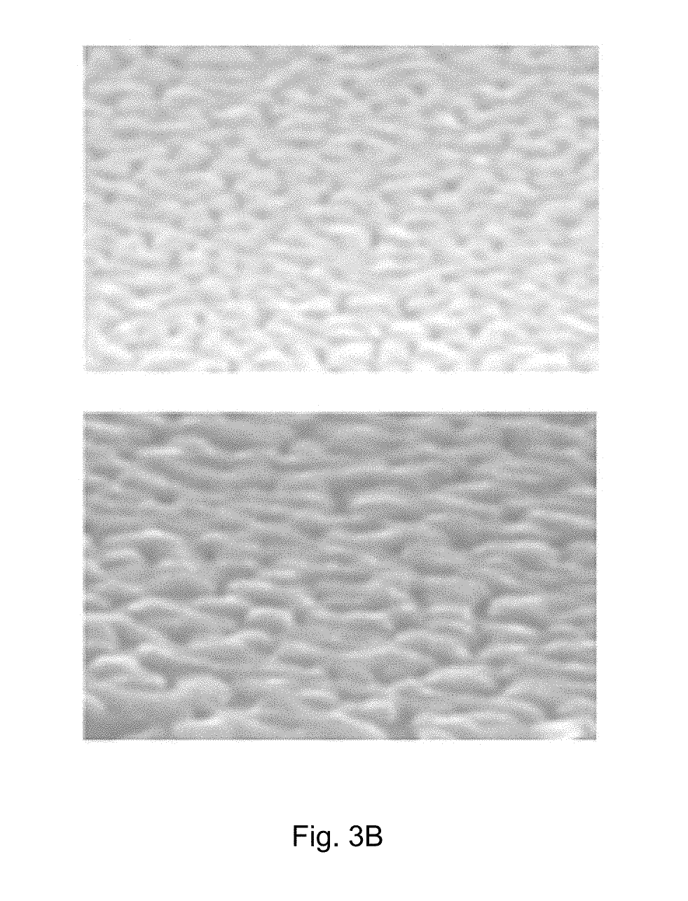

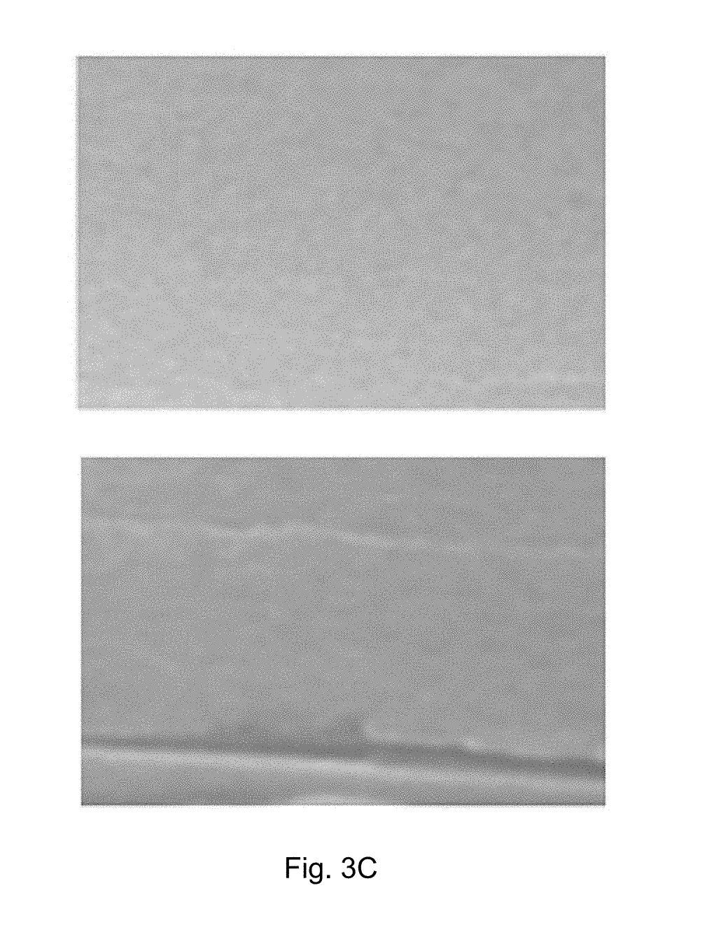

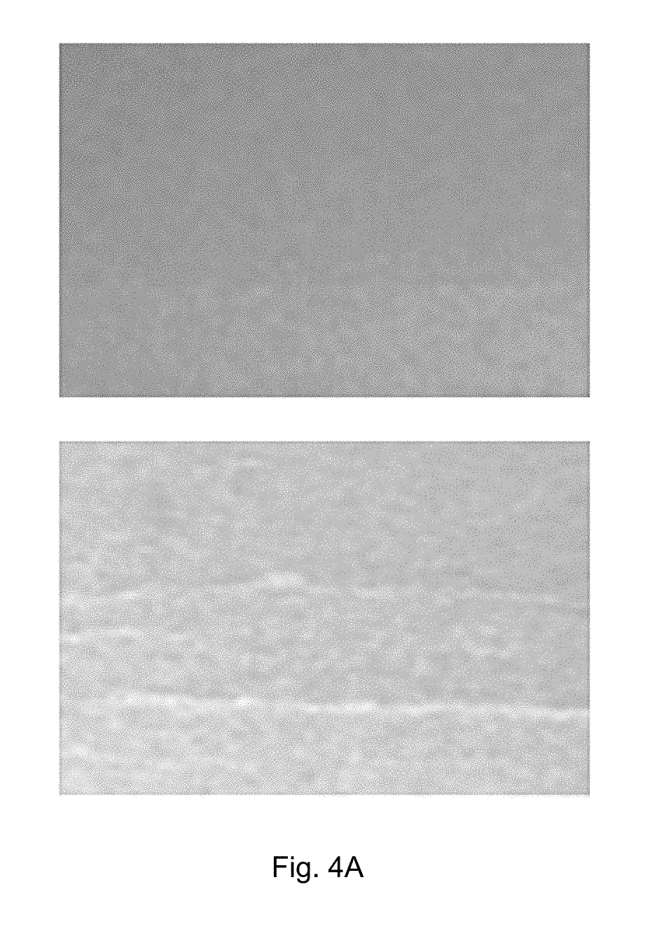

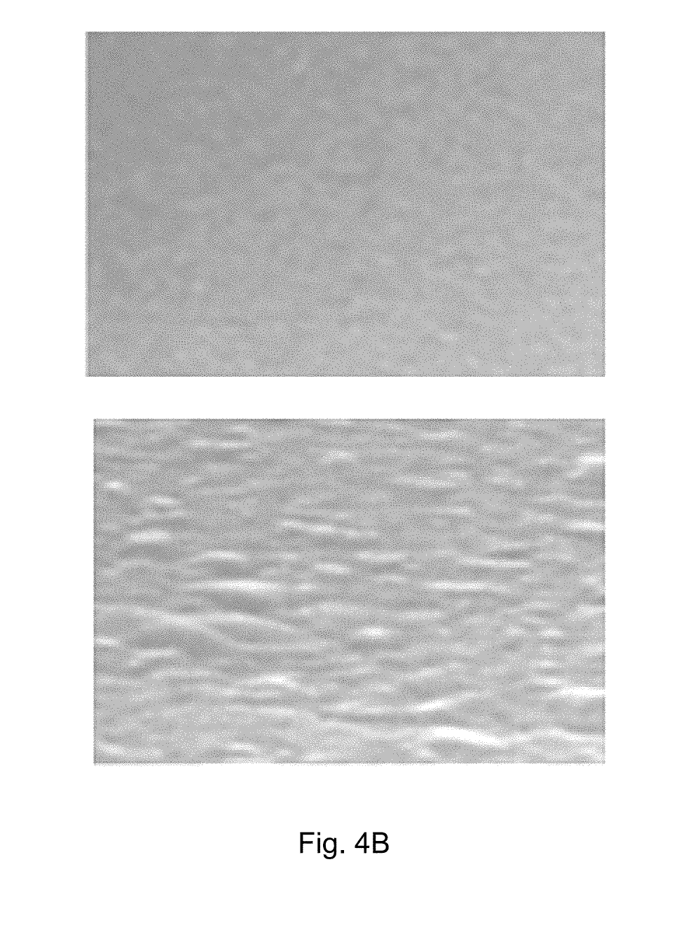

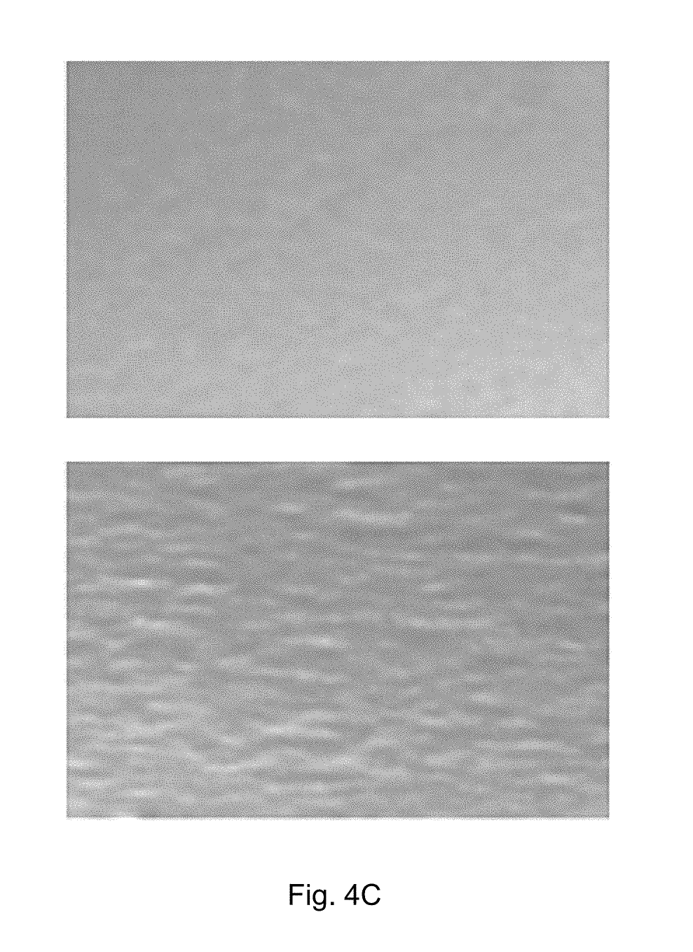

As shown in FIG. 3A and FIG. 3B, the structure 1-1 and structure 1-2 without the addition of the rare earth metal element will become larger crystals after heat treatment; as shown in FIG. 3C, the structure 1-3 without the addition of the rare earth metal element is stable before the heat treatment but the film cracking occurs after the heat treatment. As shown in FIG. 4A, FIG. 4B and FIG. 4C, the structure 2-1, the structure 2-2 and the structure 2-3 with the addition of the rare earth metal element Yb, or a mixture of the rare earth metal element Yb and the mineral salt LiF are stable before the heat treatment, and the change is small and the stability is improved and the reliability is improved after the heat treatment.

Significantly, due to the lower work function values and the stronger activity of the rare earth metal elements, it is a better choice to mix with the stable mineral salts together to form the stable layer 4. The electron injection layer of the OLED display element according to prior art is LiF having a thickness of 10 Å and the cathode is formed of Ag and magnesium (Mg) in a ratio of 9:1 and a thickness of 100 Å; in the other OLED display element applied with the present invention, the stabilized layer 4 having a thickness of 10 Å is formed with Yb and LiF in a ratio of 1:1, and then a cathode having a thickness of 100 Å is formed on the stabilizing layer 4 with Ag and Mg in a ratio of 9:1; the two OLED display elements are heat-treated at 100 Celsius degree for 1 hour, and then the respective electrical properties are experimentally tested (measurement conditions are 10 mA/cm2), and as shown in Table 2, the OLED display element according to prior art has increased the voltage by 3V after the heat treatment and the power efficiency is reduced by more than 50%, and the power consumption is significantly increased, and the OLED display element applied with the present invention has no major difference for either the voltage or the electric power efficiency before and after the heat treatment, and can be stably driven.

TABLE 2
Comparison of the electrical properties of the OLED display device
according to prior art with the OLED display element utilizing the
present invention

| | | | power |
|---|---|---|---|
| | | voltage (V) | efficiency (lm/W) |
| OLED display | before | 4.6 | 30.1 |
| element according to | heat treatment | | |
| prior art | after | 7.6 | 13.9 |
| | heat treatment | | |
| OLED display | before | 4.2 | 29.7 |
| element utilizing the | heat treatment | | |
| present invention | after | 4.2 | 29.8 |
| | heat treatment | | |

On the basis of the same inventive idea, the present invention further provides an OLED device, comprising a plurality of sub pixels. The plurality of sub pixels may emit light of at least three colors of red, green and blue. Each sub pixel comprises the aforesaid OLED display element, and the OLED display element is not described here.

In conclusion, in the OLED display element and the OLED display device of the present invention, by sandwiching the stabilizing layer comprising a rare earth metal or a mixture of the rare earth metal and a mineral salt between the second electrode and the organic layer or between the first electrode and the organic layer, the stability of the electrode thin film can be maintained to enhance the reliability of the OLED display element so that the OLED display device has the higher reliability and the better display stability.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. An OLED display element, comprising a first electrode, an organic layer and a second electrode which are stacked in order, and a stabilizing layer sandwiched between the second electrode and the organic layer or between the first electrode and the organic layer; wherein a material of the stabilizing layer comprises at least one rare earth metal.

2. The OLED display element according to claim 1, wherein the material of the stabilizing layer comprises a mixture of the rare earth metal and a mineral salt.

3. The OLED display element according to claim 1, wherein one of the first electrode and the second electrode is an anode, and the other is a cathode; one of the first electrode and the second electrode is a full transparent or translucent electrode, and the stabilizing layer is sandwiched between the full transparent or translucent electrode and the organic layer.

4. The OLED display element according to claim 1, wherein the organic layer comprises at least a hole injection layer, a hole transporting layer, an organic light emitting layer and an electron transporting layer; the first electrode is deposed on a substrate, and the second electrode is covered by a package layer.

5. The OLED display element according to claim 1, wherein a thickness of the stabilizing layer is 1-50 Å.

6. The OLED display element according to claim 2, wherein in the mixture of the rare earth metal and the mineral salt, a mass ratio of the rare earth metal and the mineral salt is 1:9-9:1.

7. The OLED display element according to claim 1, wherein a work function of the rare earth metal is not higher than 3.5 eV.

8. The OLED display element according to claim 1, wherein the rare earth metal is a mixture of one or more of lanthanum, ytterbium, cerium, europium, terbium, lutetium, samarium, neodymium and gadolinium.

9. The OLED display element according to claim 2, wherein the mineral salt is a mixture of one or more of lithium fluoride, rubidium iodide, sodium chloride, calcium carbonate and potassium bromide.

10. An OLED display device, comprising a plurality of sub pixels, and each sub pixel comprising the OLED display element according to claim 1.

11. An OLED display element, comprising a first electrode, an organic layer and a second electrode which are stacked in order, and a stabilizing layer sandwiched between the second electrode and the organic layer or between the first electrode and the organic layer; wherein a material of the stabilizing layer comprises at least one rare earth metal;
wherein the material of the stabilizing layer comprises a mixture of the rare earth metal and a mineral salt;
wherein one of the first electrode and the second electrode is an anode, and the other is a cathode; one of the first electrode and the second electrode is a full transparent or translucent electrode, and the stabilizing layer is sandwiched between the full transparent or translucent electrode and the organic layer.

12. The OLED display element according to claim 11, wherein the organic layer comprises at least a hole injection layer, a hole transporting layer, an organic light emitting layer and an electron transporting layer; the first electrode is deposed on a substrate, and the second electrode is covered by a package layer.

13. The OLED display element according to claim 11, wherein a thickness of the stabilizing layer is 1-50 Å.

14. The OLED display element according to claim 11, wherein in the mixture of the rare earth metal and the mineral salt, a mass ratio of the rare earth metal and the mineral salt is 1:9-9:1.

15. The OLED display element according to claim 11, wherein a work function of the rare earth metal is not higher than 3.5 eV.

16. The OLED display element according to claim 11, wherein the rare earth metal is a mixture of one or more of lanthanum, ytterbium, cerium, europium, terbium, lutetium, samarium, neodymium and gadolinium.

17. The OLED display element according to claim 11, wherein the mineral salt is a mixture of one or more of lithium fluoride, rubidium iodide, sodium chloride, calcium carbonate and potassium bromide.
